(19) United States
(12) Patent Application Publication
(10) Pub. No.: US 2024/0431182 A1
(43) Pub. Date: Dec. 26, 2024

(54) DISPLAY MODULE AND DISPLAY APPARATUS

(71) Applicants: Yunnan Invensight Optoelectronics Technology Co., Ltd., Kunming, Yunnan (CN); BOE Technology Group Co., Ltd., Beijing (CN)

(72) Inventors: Xiao BAI, Beijing (CN); Shengji YANG, Beijing (CN); Junyan YANG, Beijing (CN); Zhijian ZHU, Beijing (CN); Yun ZHU, Beijing (CN); Zhicheng GUO, Beijing (CN)

(21) Appl. No.: 18/699,282

(22) PCT Filed: Aug. 16, 2023
(86) PCT No.: PCT/CN2023/113335

§ 371 Date: Apr. 7, 2024

(30) Foreign Application Priority Data
Sep. 30, 2022 (CN) 202211216187.X

(51) Int. Cl. H10K 59/80

(52) U.S. Cl. CPC H10K 59/879; H10K 59/873

(57) ABSTRACT

A display module and a display apparatus. The display module comprises: a display substrate (10); a cover plate (20) located on one side of the display substrate (10); a lens layer (30) located on the side of the cover plate (20) distant from the display substrate (10); and a frame (40). The frame (40) comprises: a first fixing part (41) located on the outer side of the cover plate (20), the first fixing part (41) abutting against the lens layer (30); and a second fixing part (42) connected to the first fixing part (41), the second fixing part (42) being located between the cover plate (20) and the lens layer (30), and the second fixing part (42) abutting against the cover plate (20). A light propagation gap (50) is formed between the second fixing part (42) and the lens layer (30).

### CROSS-REFERENCE TO RELATED APPLICATION

The present application is a U.S. National Phase Entry of International Application No. PCT/CN2023/113335 having an international filing date of Aug. 16, 2023, which claims priority from Chines patent application Ser. No. 20/221,1216187.X, filed to the CNIPA on Sep. 30, 2022. Contents of the above-identified applications are incorporated into the present application by reference.

### TECHNICAL FIELD

The present disclosure relates to, but is not limited to, the field of display technologies, and particularly relates to a display module and a display apparatus.

### BACKGROUND

An Organic Light Emitting Diode (OLED) and a Quantum-dot Light Emitting Diode (QLED) are active light emitting display devices and have advantages such as self-luminescence, wide viewing angle, high contrast ratio, low power consumption, very high response speed, lightness and thinness, flexibility, and low cost. With continuous development of display technologies, a flexible display apparatus (Flexible Display) in which an OLED or a QLED is used as a light emitting device and a signal control is performed through a Thin Film Transistor (TFT) has become a mainstream product in the field of display at present.

In recent years, with the emergence of high-tech products such as AR/VR, the demand for silicon-based OLED microdisplays has been increasing. In the reality application field, a silicon-based OLED needs to be matched with an optical lens to achieve the purpose of near-eye display. At the same time, in order to better improve the reliability and optical performance of silicon-based OLED, a module form with double-layer glass cover plate is usually adopted. With the double-layer glass cover plate structure, the structure matching between the optical lens and the silicon-based OLED can be better realized.

### SUMMARY

The following is a summary of subject matter described in the present disclosure in detail. The summary is not intended to limit the scope of protection of the claims.

In a first aspect, an embodiment of the present disclosure provides a display module, including: a display substrate; a cover plate located on a side of the display substrate; a lens layer located on a side of the cover plate facing away from the display substrate; and a bezel. The bezel includes a first fixing portion positioned outside the cover plate and abutting against the lens layer; and a second fixing portion connected with the first fixing portion, the second fixing portion positioned between the cover plate and the lens layer, the second fixing portion abutting against the cover plate, and a light propagation gap being provided between the second fixing portion and the lens layer.

In an exemplary embodiment, a vertical section of the second fixing portion is rectangular or polygonal.

In an exemplary embodiment, the second fixing portion includes a side wall, a bottom wall, and a first surface connecting the side wall and the bottom wall, the side wall is connected with the first fixing portion, the bottom wall abuts against the cover plate, and the light propagation gap is provided between the first surface and the lens layer.

In an exemplary embodiment, the first surface includes at least one of a planar surface, a waved surface, a curved surface, and a stepped surface.

In an exemplary embodiment, the second fixing portion is integrally formed with the first fixing portion.

In an exemplary embodiment, orthographic projections of the second fixing portion and the display substrate on a plane where the display module is located are not overlapped.

In an exemplary embodiment, an adhesive layer is also included, and the adhesive layer is located between the second fixing portion and the cover plate, and bonds the second fixing portion and the cover plate.

In an exemplary embodiment, a surface of the second fixing portion facing the cover plate is a planar surface.

In an exemplary embodiment, the cover plate includes a first plate body and a second plate body, the first plate body is located on a side of the second plate body close to the display substrate, and an orthographic projection of the first plate body on the plane where the display module is located is positioned in an orthographic projection of the second plate body on the plane where the display module is located.

In an exemplary embodiment, the second plate body includes a light-transmitting portion and a peripheral portion positioned outside the light-transmitting portion, orthographic projections of the light-transmitting portion and the display substrate on the plane where the display module is located are overlapped, orthographic projections of the peripheral portion and the display substrate on the plane where the display module is located are not overlapped, and the second fixing portion abuts against the peripheral portion.

In an exemplary embodiment, a side wall of the peripheral portion is connected to the first fixing portion.

In an exemplary embodiment, orthographic projections of the first fixing portion and the display substrate on the plane where the display module is located are not overlapped.

In an exemplary embodiment, the cover plate is made of glass.

In an exemplary embodiment, the display substrate includes a plurality of pixel island assemblies each including a plurality of light emitting elements, the lens layer includes a plurality of microlens arrays, and the plurality of pixel island assemblies are disposed corresponding to the plurality of microlens arrays.

In a second aspect, an embodiment of the present disclosure further provides a display apparatus, including the aforementioned display module.

Other aspects of the present disclosure may be comprehended after the drawings and the detailed description are read and understood.

### BRIEF DESCRIPTION OF DRAWINGS

Accompanying drawings are used for providing an understanding of technical solutions of the present application and form a part of the specification. The drawings are used for explaining the technical solutions of the present application together with embodiments of the present application, and do not constitute a limitation on the technical solutions of the present application.

FIG. 1 is a schematic diagram of a structure of a display module according to an embodiment of the present application;

FIG. 2 is a first sectional view of a display module according to an embodiment of the present application;

FIG. 3 is a perspective view of a display module according to an embodiment of the present application;

FIG. 4 is a sectional view of a cover plate of a display module according to an embodiment of the present application;

FIG. 5a is a second sectional view of a display module according to an embodiment of the present application;

FIG. 5b is a third sectional view of a display module according to an embodiment of the present disclosure; and

FIG. 5c is a fourth sectional view of a display module according to an embodiment of the present disclosure.

### DETAILED DESCRIPTION

To make the objectives, technical solutions, and advantages of the present disclosure clearer, embodiments of the present disclosure will be described in detail below with reference to the drawings. It is to be noted that implementation modes may be implemented in various forms. Those of ordinary skills in the art can easily understand such a fact that implementation modes and contents may be transformed into various forms without departing from the purpose and scope of the present disclosure. Therefore, the present disclosure should not be explained as being only limited to the contents recorded in the following implementations. The embodiments and features in the embodiments of the present disclosure may be randomly combined with each other if there is no conflict.

In the drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the drawings schematically illustrate ideal examples, and an implementation of the present disclosure is not limited to shapes, numerical values, or the like shown in the drawings.

Ordinal numerals “first”, “second”, “third” and the like in the specification are set to avoid confusion between composition elements, but are not intended to limit in numbers.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the composition elements with reference to the drawings, which are only for the convenience of describing the present specification and simplifying the description, and do not indicate or imply that the involved devices or elements are required to have specific orientations, are structured and operated in the specific orientations, and thus should not be understood as limitations on the present disclosure. The positional relationships between the composition elements may be changed as appropriate according to a direction in which each composition element is described. Therefore, appropriate replacements based on situations are allowed, the positional relationships are not limited to the expressions described in the specification.

In the specification, unless otherwise expressly specified and defined, terms “mounting”, “connection” and “join” should be understood in a broad sense. For example, it may be a fixed connection, or a detachable connection, or an integral connection; it may be a mechanical connection or an electrical connection; it may be a direct connection, or indirect connection through an intermediate, or internal communication between two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. “An element with a certain electrical action” is not particularly limited as long as electric signals may be sent and received between the connected composition elements. Examples of the “element with a certain electrical action” not only include an electrode and a wiring, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within a range of process and measurement errors are allowed.

An embodiment of the present application provides a display module including: a display substrate; a cover plate located on a side of the display substrate; a lens layer located on a side of the cover plate facing away from the display substrate; and a bezel. The bezel includes a first fixing portion positioned outside the cover plate and abutting against the lens layer; and a second fixing portion connected with the first fixing portion, the second fixing portion positioned between the cover plate and the lens layer, and the second fixing portion abutting against the cover plate, and a light propagation gap being provided between the second fixing portion and the lens layer.

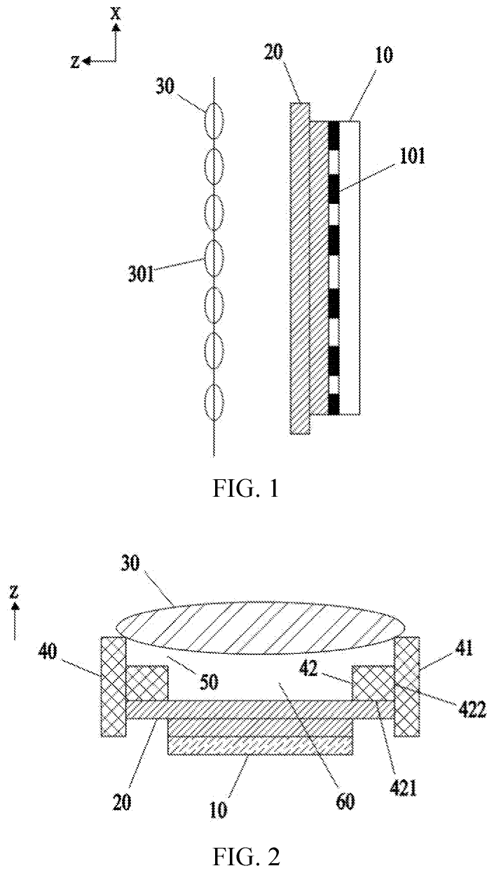

FIG. 1 is a schematic diagram of a structure of a display module according to an embodiment of the present application. In an exemplary embodiment, as shown in FIG. 1, the display module of the embodiment of the present application may be applied to a near-eye display apparatus. The display module includes a display substrate 10, a cover plate 20, and a lens layer 30. The cover plate 20 is positioned on a light-emitting side of the display substrate 10, and the lens layer 30 is positioned on a side of the cover plate 20 facing away from the display substrate 10.

In an exemplary embodiment, the display substrate 10 may include a plurality of pixel island assemblies 101 each including a plurality of light emitting elements. The lens layer 30 may include a plurality of microlens arrays 301. The plurality of pixel island assemblies 101 are disposed corresponding to the plurality of microlens arrays 301. The display module of the embodiment of the present application adopts the combination of the microlens arrays 301 and regional pixel islands (pixel island assemblies) to realize a near-eye display. Each group of microlenses-light emitting elements provides a part of a complete field of view, and an imaging beam enters the human eye and performs image angle splicing display on the retina. The display module can realize near-eye VR/AR/MR splicing display with large field of view, lightness and thinness, and high imaging ability.

In order to facilitate understanding, a working principle of the display module is briefly explained below first.

According to the embodiment of the present invention, the display module realizes display by means of beam angle splicing by utilizing the pixel island assemblies 101 and the microlens arrays 301. The pixel island assembly 101 has a plurality of regularly arranged light emitting elements, for example, may include a plurality of organic light emitting diodes (OLED) arranged in columns. Each OLED is responsible for displaying a picture in a specific angle in the overall display picture, for example, the OLED located in the center of a column is responsible for displaying a display picture from −2 to 2 degrees. The light emitted by the OLED passes through the corresponding microlens in the microlens arrays 301 and then is incident to the human eye, and a plurality of OLEDs and microlenses are combined to jointly display a display picture in a display effect such as VR or AR. Multiple parallel beams each having a certain beam width and the same angle are incident to the human eye, and focus on the same point on the retina after being converged by the crystalline lens. A microlens array 301 controls the angle connection of imaging rays emitted by light emitting elements in two adjacent pixel island assemblies 101, and a splicing display of sub-images is realized on the retina after the imaging beams are incident to the human eye.

In an exemplary embodiment, the display substrate may display an image by emitting light. The display substrate may be all kinds of flat display substrates or curved display substrates, such as liquid crystal display substrates, organic light emitting display substrates, quantum-dot light emitting display substrates, miniature light emitting diode display substrates, or electrophoretic display substrates. The display substrate may be a flexible display substrate. For example, the display substrate may be a flexible light emitting display substrate, a flexible electrophoretic display substrate, a flexible electrowetting display substrate, a flexible micro light emitting diode display substrate, or a flexible quantum-dot light emitting display substrate, but embodiments of the present disclosure are not limited thereto.

In an exemplary embodiment, the display substrate 10 may employ a silicon-based organic light emitting diode (OLED) microdisplay, which refers to a display device integrating millions or more of light emitting pixels on a base substrate (silicon-based material) with a size of less than 2 inches.

In some embodiments, the light emitting elements of the display substrate may also include a micro light emitting diode (MLED) or a quantum-dot light emitting diode (QLED).

In an exemplary embodiment, the display substrate may have a rectangular shape. In some embodiments, the display substrate may also be in a shape of a circle, an ellipse or a polygon such as a triangle, a pentagon, a hexagon or an octagon.

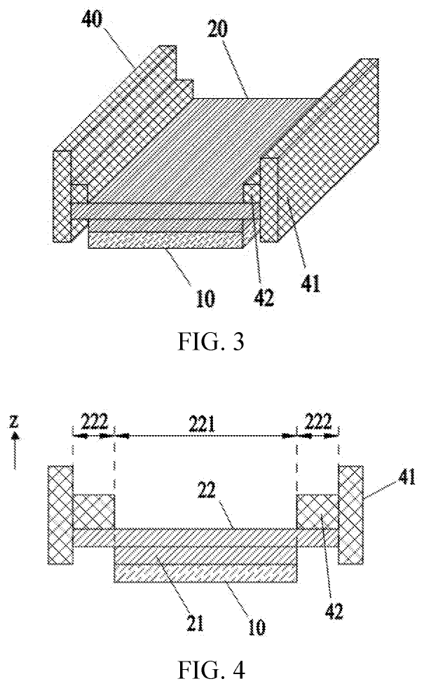

FIG. 2 is a first sectional view of a display module according to an embodiment of the present application; and FIG. 3 is a perspective view of a display module according to an embodiment of the present application. In an exemplary embodiment, as shown in FIGS. 2 and 3, in a direction perpendicular to the plane where the display module is located (direction Z), the display module of the embodiment of the present application includes a display substrate 10, a cover plate 20, a lens layer 30, and a bezel 40. The display substrate 10, the cover plate 20, and the lens layer 30 are sequentially stacked in the direction perpendicular to the plane where the display module is located, and orthographic projections of the display substrate 10, the cover plate 20 and the lens layer 30 on the plane where the display module is located are overlapped.

In an exemplary embodiment, as shown in FIGS. 2 and 3, the bezel 40 includes a first fixing portion 41 and a second fixing portion 42 connected to each other. The first fixing portion 41 has a plate-like structure and is positioned outside the display substrate 10 and the cover plate 20. For example, the first fixing portion 41 is positioned on opposite sides of the display substrate 10 and the cover plate 20. The first fixing portion 41 is close to one end of the lens layer 30 and abuts against the lens layer 30 to support the lens layer 30, so that a space 60 for light propagation is formed between the lens layer 30 and the cover plate 20. The light emitted from the display substrate 10 passes through the cover plate 20, and then passes through the space 60 for light propagation, enters the lens layer 30, and is incident to the human eye.

In an exemplary embodiment, orthographic projections of the first fixing portion 41 and the display substrate 10 on the plane where the display module is located are not overlapped, thereby preventing the first fixing portion 41 from blocking the emission of light emitted from the display substrate 10.

In an exemplary embodiment, as shown in FIGS. 2 and 3, the second fixing portion 42 has a strip shape. The second fixing portion 42 is connected to an inner wall of the first fixing portion 41 facing the cover plate 20 and is positioned between the cover plate 20 and the lens layer 30. A side of the second fixing portion 42 close to the cover plate 20 abuts against a surface of the cover plate 20, so that the second fixing portion 42 is closely attached to the surface of the cover plate 20, thereby ensuring the stability of the cover plate 20. A light propagation gap 50 is provided between the lens layer 30 and a side of the second fixing portion 42 close to the lens layer 30, and the lateral light emitted from the display substrate 10 can pass through the light propagation gap 50 and enter the lens layer 30, thereby improving the light output rate of the lateral light emitted from the display substrate 10 and preventing the lateral light emitted from the display substrate 10 from being blocked by the second fixing portion 42.

In an exemplary embodiment, as shown in FIGS. 2 and 3, orthographic projections of the second fixing portion 42 and the display substrate 10 on the plane where the display module is located are not overlapped, thereby preventing the second fixing portion 42 from blocking the emission of light emitted from the display substrate 10.

The structure of the bezel of the display module of the embodiment of the present application solves the problem that the lateral light emitted by the display substrate 10 is blocked through the light propagation gap 50, and improves the light output rate of the lateral light emitted by the display substrate 10; and the stability of the cover plate 20 can be ensured by the second fixing portion 42. At the same time, the structure of the bezel of the display module in the embodiment of the present application does not increase the size of the display module.

In an exemplary embodiment, the vertical section of the second fixing portion may be rectangular or polygonal. The polygon can include a pentagon, a hexagon, etc. In an example, the vertical section of the second fixing portion 42 may be rectangular. The second fixing portion 42 includes a bottom wall 421 and a side wall 422, and the side wall 422 on a side of the second fixing portion 42 close to the first fixing portion 41 is connected to the first fixing portion 41. The bottom wall 421 of the second fixing portion 42 is a surface on a side close to the cover plate 20. The bottom wall 421 of the second fixing portion 42 abuts against a surface of the cover plate 20 to ensure a contact area between the second fixing portion 42 and the cover plate 20, thereby ensuring the stability of the display module, as shown in FIG. 2.

In an exemplary embodiment, the surface of the second fixing portion 42 facing the cover plate 20 is a planar surface, and the second fixing portion 42 abuts against the cover plate 20 through the planar surface, so as to ensure the contact area between the second fixing portion 42 and the cover plate 20, thereby ensuring the stability of the display module.

In some embodiments, the surface of the second fixing portion facing the cover plate may also be of a non-planar structure. For example, the surface of the second fixing portion facing the cover plate may also be a waved surface or a cambered surface or the like, which is not repeated in the embodiments of the present application.

In an exemplary embodiment, the first fixing portion 41 and the second fixing portion 42 may be integrally formed to ensure the stability of the bezel 40. In an example, the first fixing portion 41 and the second fixing portion 42 are both made of plastic, and the first fixing portion 41 and the second fixing portion 42 are injection molded as a whole.

In some embodiments, the first fixing portion and the second fixing portion may also be connected to each other as two independent components. For example, the first fixing portion and the second fixing portion are bonded to each other, which is not repeated in the embodiments of the present application.

In an exemplary embodiment, the display module of the embodiment of the present application further includes an adhesive layer positioned between the second fixing portion 42 and the cover plate 20, and the adhesive layer bonds the second fixing portion 42 and the cover plate 20 to improve the strength of the connection between the second fixing portion 42 and the cover plate 20.

FIG. 4 is a sectional view of a cover plate of a display module according to an embodiment of the present application. In an exemplary embodiment, as shown in FIG. 4, the cover plate 20 of the display module of the embodiment of the present application includes a first plate body 21 and a second plate body 22, which are stacked along a direction perpendicular to the plane where the display module is located. The first plate body 21 is positioned on a side of the second plate body 22 close to the display substrate 10. Orthographic projections of the first plate body 21 and the display substrate 10 on the plane where the display module is located are overlapped. In an example, an orthographic projection of the first plate body 21 on the plane where the display module is located is completely overlapped with an orthographic projection of the display substrate 10 on the plane where the display module is located. An orthographic projection of the first plate body 21 on the plane where the display module is located is positioned in an orthographic projection of the second plate body 22 on the plane where the display module is located, and an area of the orthographic projection of the first plate body 21 on the plane where the display module is located is smaller than an area of the orthographic projection of the second plate body 22 on the plane where the display module is located, so that an edge of the first plate body 21 and an edge of the second plate body 22 form a step shape.

In an exemplary embodiment, as shown in FIG. 4, the second plate body 22 includes a light-transmitting portion 221 and a peripheral portion 222 positioned outside the light-transmitting portion 221. Orthographic projections of the light-transmitting portion 221 and each of the first plate body 21 and the display substrate 10 on the plane where the display module is located are overlapped. In an example, an orthographic projection of the light-transmitting portion 221 on the plane where the display module is located is completely overlapped with each of orthographic projections of the first plate body 21 and the display substrate 10 on the plane where the display module is located. The light-transmitting portion 221 transmits the light emitted from the display substrate 10 and causes the light emitted from the display substrate 10 to enter the space 60 for light propagation.

In an exemplary embodiment, as shown in FIG. 4, orthographic projections of the peripheral portion 222 and each of the first plate body 21 and the display substrate 10 on the plane where the display module is located are not overlapped, and orthographic projections of the second fixing portion 42 of the bezel 40 and the peripheral portion 222 on the plane where the display module is located are overlapped, and an orthographic projection of the second fixing portion 42 on the plane where the display module is located is not overlapped with the orthographic projection of the light-transmitting portion 221 on the plane where the display module is located. The second fixing portion 42 abuts against the peripheral portion 222, thereby preventing the second fixing portion 42 from occupying the space of the light-transmitting portion 221 and affecting the transmittance of light emitted by the display substrate 10.

In an exemplary embodiment, as shown in FIG. 4, a side wall of the peripheral portion 222 is connected to a side wall of the first fixing portion 41. For example, the side wall of the peripheral portion 222 is in contact with the side wall of the first fixing portion 41. Alternatively, there is a gap between the side wall of the peripheral portion 222 and the side wall of the first fixing portion 41.

In an exemplary embodiment, the cover plate 20 may be made of a light-transmitting material. For example, the cover plate 20 may be made of a glass material, i.e. the first plate body 21 and the second plate body 22 may be made of a glass material.

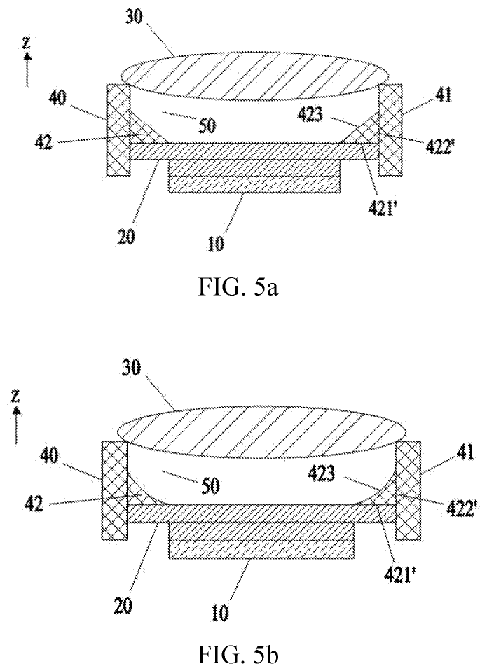

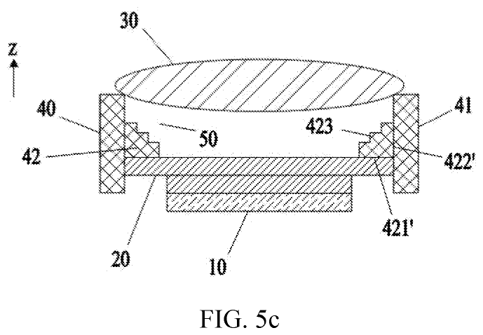

FIG. 5a is a second sectional view of a display module according to an embodiment of the present application; FIG. 5b is a third sectional view of a display module according to an embodiment of the present application; and FIG. 5c is a fourth sectional view of a display module according to an embodiment of the present application. In an exemplary embodiment, as shown in FIGS. 5a, 5b and 5c, the vertical section of the second fixing portion 42 is triangular, and the second fixing portion 42 includes a bottom wall 421′, a side wall 422′, and a first surface 423 connecting the bottom wall 421′ and the side wall 422′, and an included angle can be formed between the bottom wall 421′ and the side wall 422′. For example, an included angle of 90 degrees can be formed between the bottom wall 421′ and the side wall 422′, i.e. the bottom wall 421′ and the side wall 422′ are disposed perpendicular to each other. The first surface 423 may form an acute angle with the bottom wall 421′. The bottom wall 421′ of the second fixing portion 42 is a surface close to the cover plate 20. The bottom wall 421′ of the second fixing portion 42 abuts against a surface of the cover plate 20. The side wall 422′ of the second fixing portion 42 is connected to an inner wall of the first fixing portion 41. A light propagation gap 50 is provided between the first surface 423 of the second fixing portion 42 and the lens layer 30.

In an exemplary embodiment, the first surface 423 of the second fixing portion 42 may take a variety of structures. For example, the first surface 423 of the second fixing portion 42 may be a planar surface as shown in FIG. 5a. Alternatively, the first surface 423 of the second fixing portion 42 may be a curved surface recessed inward as shown in FIG. 5b. Alternatively, the first surface 423 of the second fixing portion 42 may be a stepped surface including a plurality of step structures as shown in FIG. 5c. Alternatively, the first surface of the second fixing portion may be a waved surface.

Compared with the second fixing portion with a rectangular vertical section, the first surface of the second fixing portion with a triangular vertical section in the display module according to the embodiment of the present application can further enlarge the space of the light propagation gap 50, reduce the blocking of the lateral light of the display substrate 10, and improve the light output rate of the lateral light of the display substrate 10.

An embodiment of the present application further provides a display apparatus, including the display module described in any one of above embodiments. The display apparatus includes a mobile phone, a tablet computer, a wearable smart product (such as a smart watch, a bracelet, or the like), a personal digital assistant (PDA), a vehicle-mounted computer, or the like. A specific form of the display apparatus is not specially limited in the embodiments of the present application.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display module, comprising:
a display substrate;
a cover plate located on a side of the display substrate;
a lens layer located on a side of the cover plate facing away from the display substrate;
a bezel comprising:
a first fixing portion positioned outside the cover plate and abutting against the lens layer;
a second fixing portion connected with the first fixing portion, the second fixing portion positioned between the cover plate and the lens layer, the second fixing portion abutting against the cover plate; and a light propagation gap being provided between the second fixing portion and the lens layer.

2. The display module according to claim 1, wherein a vertical section of the second fixing portion is rectangular or polygonal.

3. The display module according to claim 1, wherein the second fixing portion comprises a side wall, a bottom wall and a first surface connecting the side wall and the bottom wall, the side wall is connected with the first fixing portion, the bottom wall abuts against the cover plate, and the light propagation gap is provided between the first surface and the lens layer.

4. The display module according to claim 3, wherein the first surface comprises at least one of a planar surface, a waved surface, a curved surface and a stepped surface.

5. The display module according to claim 1, wherein the second fixing portion is integrally formed with the first fixing portion.

6. The display module according to claim 1, wherein orthographic projections of the second fixing portion and the display substrate on a plane where the display module is located are not overlapped.

7. The display module according to claim 1, further comprising an adhesive layer positioned between the second fixing portion and the cover plate and bonding the second fixing portion and the cover plate.

8. The display module according to claim 1, wherein a surface of the second fixing portion facing the cover plate is a planar surface.

9. The display module according to claim 1, wherein the cover plate comprises a first plate body and a second plate body, the first plate body is located on a side of the second plate body close to the display substrate, and an orthographic projection of the first plate body on a plane where the display module is located is positioned in an orthographic projection of the second plate body on the plane where the display module is located.

10. The display module according to claim 9, wherein the second plate body comprises a light-transmitting portion and a peripheral portion positioned outside the light-transmitting portion, orthographic projections of the light-transmitting portion and the display substrate on the plane where the display module is located are overlapped, orthographic projections of the peripheral portion and the display substrate on the plane where the display module is located are not overlapped, and the second fixing portion abuts against the peripheral portion.

11. The display module according to claim 10, wherein a side wall of the peripheral portion is connected to the first fixing portion.

12. The display module according to claim 1, wherein orthographic projections of the first fixing portion and the display substrate on a plane where the display module is located are not overlapped.

13. The display module according to claim 1, wherein the cover plate is made of glass.

14. The display module according to claim 1, wherein the display substrate comprises a plurality of pixel island assemblies each comprising a plurality of light emitting elements, and the lens layer comprises a plurality of microlens arrays, and the plurality of pixel island assemblies are disposed corresponding to the plurality of microlens arrays.

15. A display apparatus, comprising the display module according to claim 1.

16. The display module according to claim 2, wherein the second fixing portion is integrally formed with the first fixing portion.

17. The display module according to claim 2, wherein orthographic projections of the second fixing portion and the display substrate on a plane where the display module is located are not overlapped.

18. The display module according to claim 2, further comprising an adhesive layer positioned between the second fixing portion and the cover plate and bonding the second fixing portion and the cover plate.

19. The display module according to claim 2, wherein a surface of the second fixing portion facing the cover plate is a planar surface.

20. The display module according to claim 2, wherein the cover plate comprises a first plate body and a second plate body, the first plate body is located on a side of the second plate body close to the display substrate, and an orthographic projection of the first plate body on a plane where the display module is located is positioned in an orthographic projection of the second plate body on the plane where the display module is located.
